(19) United States
(12) Patent Application Publication
(10) Pub. No.: US 2007/0215043 A1
(43) Pub. Date: Sep. 20, 2007

(54) SUBSTRATE PROCESSING APPARATUS, DEPOSIT MONITORING APPARATUS, AND DEPOSIT MONITORING METHOD

(75) Inventors: Yohei YAMAZAWA, Nirasaki-shi (JP); Tatsuo MATSUDO, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/685,307

(22) Filed: Mar. 13, 2007

Related U.S. Application Data
(60) Provisional application No. 60/788,109, filed on Apr. 3, 2006.

(30) Foreign Application Priority Data
Mar. 20, 2006 (JP) 2006-077264

(51) Int. Cl. B05C 11/00; C23C 14/54

(52) U.S. Cl. 118/665; 427/9

(57) ABSTRACT

A substrate processing apparatus capable of improving the degree of freedom for installation of a deposit monitoring apparatus component used for direct deposit analysis. A deposit monitoring apparatus of the substrate processing apparatus for monitoring deposit in a processing chamber in which a substrate is processed includes an optical fiber having a portion thereof exposed in the processing chamber. Incident light is emitted to the optical fiber from a light-emitting device connected to one end of the optical fiber, and light having passed through the optical fiber is received by a light-receiving device connected to another end of the optical fiber.

### BACKGROUND OF THE INVENTION

1. Field of the Invention

This invention relates to a substrate processing apparatus, a deposit monitoring apparatus, and a deposit monitoring method, and more particularly, to a substrate processing apparatus including a deposit monitoring apparatus for implementing a deposit monitoring method capable of monitoring deposit in a processing chamber (chamber) in which predetermined processing is carried out on a substrate to be processed.

2. Description of the Related Art

In plasma processing for manufacturing semiconductor chips, etching of a thin film formed on a semiconductor wafer (hereinafter referred to simply as “wafer”) as a substrate to be processed is carried out in a vessel (chamber) housing the wafer, or CVD (Chemical Vapor Deposition) for depositing a predetermined material on a wafer to form a thin film is carried out therein.

CVD is a process for growing a thin film of a predetermined material on a wafer, and hence a deposit of the predetermined material becomes inevitably attached to the inner wall of the vessel. On the other hand, in etching, a film formed on a wafer is removed through chemical reaction or sputtering, and a reaction product produced at this time becomes attached as a deposit to the inner wall of the vessel. Thus, the inner wall of the vessel is contaminated with deposit during the plasma processing. If the inner wall of the vessel is severely contaminated with deposit, the distribution of plasma or the like in the vessel is affected, and therefore the reproducibility of the plasma processing is deteriorated.

In a mass production plant of semiconductor devices, the interior of a vessel of a substrate processing apparatus used as an apparatus for production of semiconductor devices is regularly cleaned to maintain the reproducibility of the plasma processing in the substrate processing apparatus.

The period of the cleaning is estimated by a statistical method based on cumulative discharge time of high frequency electric power in a vessel when the reproducibility of the plasma processing becomes difficult, or based on the number of wafers having been processed.

Instead of the aforementioned statistic method, there has been proposed a method for semi-quantitatively or directly analyzing a deposit on the inner wall of a vessel and for determining the period of cleaning, specifically the start time of cleaning, with much higher accuracy (see, for example, Japanese Patent Laid-Open No. H07-086254 (FIG. 8)).

In the method capable of directly analyzing a deposit, an internal reflection prism, which is a transparent member fabricated into substantially a U shape, is first mounted to a chamber in such a manner that a surface of the prism is exposed into the chamber. Incident light incoming from an optical fiber and entering one end of the internal reflection prism passes through the prism, while being internally reflected. Incident light having passed through the prism is received by a light-receiving device, which is connected via an optical fiber to another end of the prism. The light received by the light-receiving device in this manner is monitored by a photoreceiver or the like.

There occurs a change in the intensity or the like of light monitored when a deposit attached to the surface of the transparent member absorbs or reflects light passing through the transparent member while being internally reflected. Based on the change, the deposit attached to the surface of the internal reflection prism can be analyzed.

However, in the aforementioned method allowing direct analysis, it is necessary for the transparent member such as the internal reflection prism to be prepared to have a size large enough to facilitate the attachment of the transparent member to the chamber. When installed on the surface of the inner wall of the chamber, the transparent member thus prepared largely protrudes from the surface of the inner wall depending on the installation location. This may be a cause of an abnormal discharge during the plasma processing. Thus, the transparent member having a desired size is limited in its installation location and hence low in the degree of freedom for installation.

### SUMMARY OF THE INVENTION

The present invention provides a substrate processing apparatus, a deposit monitoring apparatus and a deposit monitoring method that are capable of improving the degree of freedom for installation of a deposit monitoring apparatus component used for direct deposit analysis.

According to a first aspect of the present invention, there is provided a substrate processing apparatus comprising a deposit monitoring apparatus adapted to monitor deposit in a processing chamber in which predetermined processing is carried out on a substrate to be processed, wherein the deposit monitoring apparatus comprises an optical fiber disposed so as to be at least partly exposed in the processing chamber, a light-emitting device connected to one end of the optical fiber and adapted to emit incident light to the optical fiber, and a light-receiving device connected to another end of the optical fiber and adapted to receive light having passed through the optical fiber.

According to the first aspect of the present invention, a deposit can be monitored using the exposed portion of the optical fiber which is disposed in the processing chamber, whereby the degree of freedom for installation of a deposit monitoring apparatus component (the optical fiber) can be improved.

The light-emitting device can comprise at least one light source adapted to emit light having a single wavelength, and the light-receiving device can comprise an optical sensor adapted to detect at least one of an amount of the received light and an intensity of the received light.

In this case, when a deposit is attached to a surface of the optical fiber exposed in the processing chamber, at least part of light passing through the optical fiber while being repeatedly internally reflected in the optical fiber by the surface of the optical fiber is absorbed or reflected by the deposit. The ratios of absorption and reflection of light by the deposit vary depending on the thickness of the deposit. As a result, there occurs a change in the amount and the intensity of light which is passing through the optical fiber. By detecting at least one of the amount and the intensity of light received by the light-receiving device, information about the deposit thickness can be optically acquired.

The single wavelength can be different from a wavelength of light emitted in the processing chamber.

In this case, since the wavelength of the light source is different from the wavelength of light emitted in the processing chamber, the deposit can be directly analyzed with high accuracy.

The substrate processing apparatus can comprise a calculation apparatus adapted to calculate a thickness of deposit attached to a surface of an exposed portion of the optical fiber based on a result of monitoring by the deposit monitoring apparatus.

In this case, since the thickness of deposit attached to the surface of the exposed optical fiber is calculated based on the result of monitoring by the deposit monitoring apparatus, the timing at which cleaning should be carried out to remove the deposit can be determined based on an actual state within the processing chamber.

The light-emitting device can comprise a light source adapted to emit light having wavelengths in a wideband spectral range, and the light-receiving device can comprise a spectrometer adapted to separate the received light into a spectrum of wavelengths.

In this case, when a deposit is deposited on the surface of the optical fiber exposed in the processing chamber, the deposit absorbs, from incident light reflected at the surface, light having wavelengths corresponding to the components and the composition of the deposit. The absorption of light by the deposit is represented by an absorption spectrum when light having passed through the optical fiber is separated into a spectrum of wavelengths. Thus, information about at least the components of the deposit can be optically acquired.

The substrate processing apparatus can comprise a spectrum creating apparatus adapted to create a spectral distribution of the light separated into the spectrum of wavelengths.

In this case, since a spectral distribution is created, a clear absorption spectrum can be obtained, and information about the components of the deposit can be reliably acquired.

The deposit monitoring apparatus can analyze components of the deposit.

In this case, since the components of a deposit are analyzed, control can be performed based on the components of the deposit.

A surface of at least an exposed portion of the optical fiber can be mirror-finished.

In this case, since the surface of the exposed optical fiber is mirror-finished, the surface of the exposed optical fiber is microscopically flat, so that irregular reflection of light at the surface of the exposed optical fiber can be prevented. As a result, reflection by a deposit largely contributes to reflection of light at the surface of the exposed optical fiber, and the detection accuracy of the light-receiving device can be improved.

The light-emitting device and the light-receiving device can be disposed outside the processing chamber.

In this case, since the light-emitting device and the light-receiving device are disposed outside the processing chamber, the deposit monitoring apparatus can be easily attached and detached.

A groove in which an exposed portion of the optical fiber is disposed can be formed in the processing chamber.

In this case, since the exposed optical fiber is disposed in the groove formed in the processing chamber, the exposed optical fiber can be prevented from protruding from the surface of the processing chamber, making it possible to prevent an abnormal discharge due to the presence of projection from occurring in the processing chamber.

The substrate processing apparatus can comprise a controller adapted to perform feedback control based on a result of monitoring by the deposit monitoring apparatus.

In this case, since feedback control is performed based on the result of monitoring, the reliability of control of the substrate processing apparatus can be improved.

According to a second aspect of the present invention, there is provided a deposit monitoring apparatus for monitoring deposit in a processing chamber in which predetermined processing is carried out on a substrate to be processed, comprising an optical fiber disposed so as to be at least partly exposed in the processing chamber, a light-emitting device connected to one end of the optical fiber and adapted to emit incident light to the optical fiber, and a light-receiving device connected to another end of the optical fiber and adapted to receive light having passed through the optical fiber.

According to a third aspect of the present invention, there is provided a deposit monitoring method for monitoring deposit in a processing chamber in which predetermined processing is carried out on a substrate to be processed, comprising a light emitting step of emitting incident light to one end of an optical fiber disposed so as to be at least partly exposed in the processing chamber, and a light receiving step of receiving light having passed through the optical fiber from another end of the optical fiber.

The above and other objects, features, and advantages of the invention will become more apparent from the following detailed description taken in conjunction with the accompanying drawings.

### BRIEF DESCRIPTION OF THE DRAWINGS

FIG. 1 is a sectional view schematically showing the construction of a substrate processing apparatus according to an embodiment of the present invention;

FIG. 2 is a fragmentary sectional view schematically showing the construction of a deposit monitoring apparatus installed on an inner wall of a chamber shown in FIG. 1; and

FIG. 3 is a fragmentary sectional view schematically showing the construction of a modification of the deposit monitoring apparatus shown in FIG. 2.

### DETAILED DESCRIPTION OF THE PREFERRED EMBODIMENT

An embodiment of the present invention will be described below with reference to the drawings.

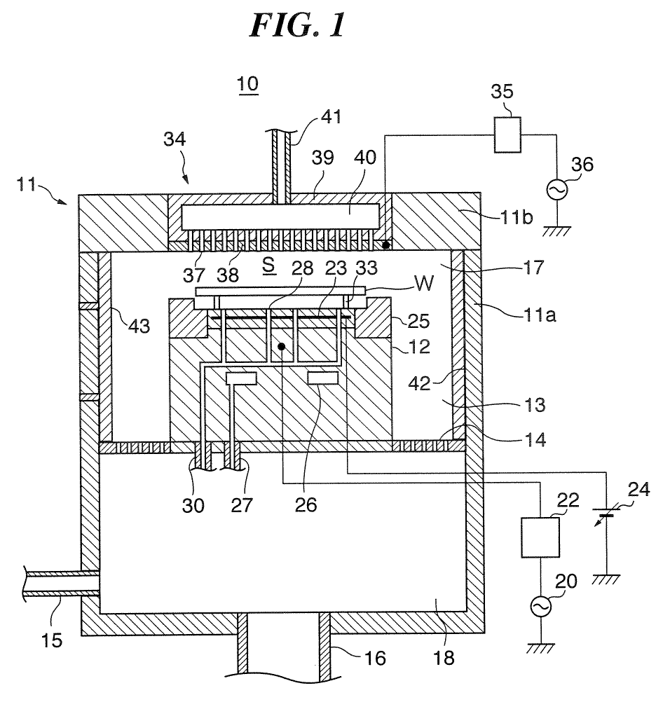

FIG. 1 is a sectional view schematically showing the construction of a substrate processing apparatus according to an embodiment of the present invention. This substrate processing apparatus is configured to carry out etching processing on a semiconductor wafer as a substrate to be processed.

As shown in FIG. 1, the substrate processing apparatus 10 has a cylindrical chamber 11 (processing chamber) housing a semiconductor wafer (hereinafter referred to simply as “the wafer”) W having a diameter of, for example, 300 mm. A cylindrical susceptor 12 is disposed in the chamber 11 as a stage on which the wafer W is mounted.

In the substrate processing apparatus 10, a side exhaust channel 13 that acts as a flow path through which gas above the susceptor 12 is exhausted out of the chamber 11 is formed between an inner wall 11a of the chamber 11 and a side face of the susceptor 12. A baffle plate 14 is disposed part way along the side exhaust path 13.

The baffle plate 14 is a plate-shaped member having a large number of holes therein, and acts as a partitioning plate that partitions the chamber 11 into an upper portion and a lower portion. Plasma, described below, is produced in the upper portion (hereinafter referred to as the “reaction chamber”) 17 of the chamber 11 partitioned by the baffle plate 14. The susceptor 12 is disposed on a bottom portion of the reaction chamber 17. Moreover, a roughing exhaust pipe 15 and a main exhaust pipe 16 that exhaust gas out from the chamber 11 are opened to the lower portion (hereinafter referred to as the “manifold”) 18 of the chamber 11. The roughing exhaust pipe 15 has a DP (dry pump) (not shown) connected thereto, and the main exhaust pipe 16 has a TMP (turbo-molecular pump) (not shown) connected thereto. Moreover, the baffle plate 14 captures or reflects ions and radicals produced in a processing space S, described below, in the reaction chamber 17, thus preventing leakage of the ions and radicals into the manifold 18.

The roughing exhaust pipe 15 and the main exhaust pipe 16 exhaust gas in the reaction chamber 17 out of the chamber 11 via the manifold 18. Specifically, the roughing exhaust pipe 15 reduces the pressure in the chamber 11 from atmospheric pressure down to a low vacuum state, and the main exhaust pipe 16 is operated in collaboration with the roughing exhaust pipe 15 to reduce the pressure in the chamber 11 from atmospheric pressure down to a high vacuum state (e.g. a pressure of not more than 133 Pa (1 torr)), which is at a lower pressure than the low vacuum state.

A lower radio frequency power source 20 is connected to the susceptor 12 via a matcher 22. The lower radio frequency power source 20 supplies predetermined radio frequency electrical power to the susceptor 12. The susceptor 12 thus acts as a lower electrode. The matcher 22 reduces reflection of the radio frequency electrical power from the susceptor 12 so as to maximize the efficiency of the supply of the radio frequency electrical power into the susceptor 12.

A disk-shaped ESC electrode plate 23 comprised of an electrically conductive film is provided in an upper portion of the susceptor 12. A DC power source 24 is electrically connected to the ESC electrode plate 23. A wafer W is attracted to and held on an upper surface of the susceptor 12 through a Johnsen-Rahbek force or a Coulomb force generated by a DC voltage applied to the ESC electrode plate 23 from the DC power source 24. Moreover, an annular focus ring 25 is provided on an upper portion of the susceptor 12 so as to surround the wafer W attracted to and held on the upper surface of the susceptor 12. The focus ring 25 is exposed to the processing space S, and focuses the plasma in the processing space S toward a surface of the wafer W, thus improving the efficiency of the etching processing.

An annular coolant chamber 26 that extends, for example, in a circumferential direction of the susceptor 12 is provided inside the susceptor 12. A coolant, for example cooling water or a Galden (registered trademark) fluid, at a predetermined temperature is circulated through the coolant chamber 26 via coolant piping 27 from a chiller unit (not shown). A processing temperature of the wafer W attracted to and held on the upper surface of the susceptor 12 is controlled through the temperature of the coolant.

A plurality of heat-transmitting gas supply holes 28 are opened to a portion of the upper surface of the susceptor 12 on which the wafer W is attracted and held (hereinafter referred to as the “attracting surface”) The heat-transmitting gas supply holes 28 are connected to a heat-transmitting gas supply unit (not shown) by a heat-transmitting gas supply line 30. The heat-transmitting gas supply unit supplies helium gas as a heat-transmitting gas via the heat-transmitting gas supply holes 28 into a gap between the attracting surface of the susceptor 12 and a rear surface of the wafer W. The helium gas supplied into the gap between the attracting surface of the susceptor 12 and the rear surface of the wafer W transmits heat from the wafer W to the susceptor 12.

A plurality of pusher pins 33 are provided in the attracting surface of the susceptor 12 as lifting pins that can be made to project out from the upper surface of the susceptor 12. The pusher pins 33 are connected to a motor (not shown) by a ball screw (not shown), and can be made to project out from the attracting surface of the susceptor 12 through rotational motion of the motor, which is converted into linear motion by the ball screw. The pusher pins 33 are housed inside the susceptor 12 when a wafer W is being attracted to and held on the attracting surface of the susceptor 12 so that the wafer W can be subjected to the etching processing, and are made to project out from the upper surface of the susceptor 12 so as to lift the wafer W up away from the susceptor 12 when the wafer W is to be transferred out from the chamber 11 after having been subjected to the etching processing.

A gas introducing shower head 34 is disposed in a ceiling portion 11b of the chamber 11 facing the susceptor 12 with the reaction chamber 17 therebetween. An upper radio frequency power source 36 is connected to the gas introducing shower head 34 via a matcher 35. The upper radio frequency power source 36 supplies predetermined radio frequency electrical power to the gas introducing shower head 34. The gas introducing shower head 34 thus acts as an upper electrode. The matcher 35 has a similar function to the matcher 22, described earlier.

The gas introducing shower head 34 has a ceiling electrode plate 38 having a large number of gas holes 37 therein, and an electrode support 39 on which the ceiling electrode plate 38 is detachably supported. A buffer chamber 40 is provided inside the electrode support 39. A processing gas introducing pipe 41 is connected to the buffer chamber 40. A processing gas supplied from the processing gas introducing pipe 41 into the buffer chamber 40 is supplied by the gas introducing shower head 34 into the chamber 11 (the reaction chamber 17) via the gas holes 37.

A deposit shield 43 is disposed as a side wall component on the inner wall 11a of the chamber 11 such as to cover the inner wall 11a and face onto the processing space S between the susceptor 12 and the gas introducing shower head 34. The deposit shield 43 is a cylindrical component made of an insulating material such as yttria (Y₂O₃), and is disposed such as to surround the susceptor 12.

Radio frequency electrical power is supplied to the susceptor 12 and the gas introducing shower head 34 in the chamber 11 of the substrate processing apparatus 10 as described above so as to apply radio frequency electrical power into the processing space S, whereupon the processing gas supplied into the processing space S from the gas introducing shower head 34 is turned into high-density plasma, whereby ions and radicals are produced; the wafer W is subjected to the etching processing by the ions and so on.

Operation of the component elements of the substrate processing apparatus 10 described above is controlled in accordance with a program for the etching processing by a CPU of a control unit (not shown) of the substrate processing apparatus 10.

In the substrate processing apparatus 10, when a wafer W is subjected to the etching processing, the ions and so on react with matter present on the surface of the wafer so that a reaction product is produced. The reaction product becomes attached as deposit to the deposit shield 43, and the inner wall 11a and the ceiling portion 11b of the chamber 11, and then the attached reaction product is detached during subsequent etching processing or the like, thus forming particles. The particles float through the reaction chamber 17, in particular the processing space S, and thus become attached as deposit to the surface of a wafer W. For the substrate processing apparatus 10, cleaning of the interior of the chamber 11 must thus be carried out to remove such deposit.

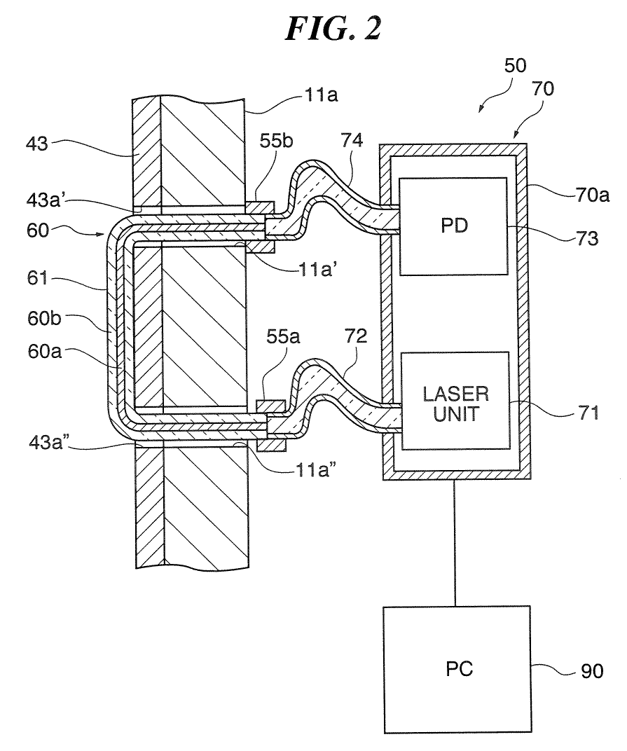

FIG. 2 is a sectional view schematically showing the construction of a deposit monitoring apparatus installed in the inner wall 11a of the chamber 11 appearing in FIG. 1.

The deposit monitoring apparatus 50 shown in FIG. 2 is for monitoring deposit attached to the inner wall surface of the chamber 11 in which predetermined processing is carried out on the wafer W. The deposit monitoring apparatus 50 includes an optical fiber 60 formed into a wire shape having a diameter of, for example, 0.2 mm, a laser unit 71 as a light-emitting device from which light is incident on the optical fiber 60, and a photodiode (PD) 73 as a light-receiving device which receives light having passed through the optical fiber 60. The light source such as the laser unit 71 is not limited to one in number, and a plurality of light sources may be used.

The optical fiber 60 is disposed to extend through narrow holes 11a′, 11a″ formed on the inner wall 11a of the chamber 11 and narrow holes 43a′, 43a″ formed on the deposit shield 43. An exposed portion 61 of the optical fiber 60, which is an optical fiber portion exposed into the chamber 11 (exposed optical fiber), is disposed to extend along a surface of the deposit shield 43, and its length is defined by the distance between the narrow holes 43a′, 43a″. By making a plurality of substrate processing apparatuses 10 to have the same distance between the narrow holes 43a′, 43a″, the length of the exposed portion 61 can easily be made uniform between the plurality of substrate processing apparatuses 10.

The optical fiber 60 is composed of a transparent holey fiber. Even if the holey fiber is bent to a right angle, an optical signal is not interrupted in passing through the holey fiber. The holey fiber is a glass fiber formed with a plurality of, for example six, groove-like air holes (not shown). Specifically, the optical fiber 60 is a transparent member comprised of a core 60a along which light propagates and a clad 60b which surrounds the core 60a, wherein the core 60a is surrounded by six air holes and formed integrally with the clad 60b. The six air holes have an effect of increasing a difference in refractive index between the peripheries of the air holes, namely a difference in refractive index between the core 60a and the clad 60b. With the increase in difference in refractive index, the effect of confining light within the core 60a is enhanced, resulting in excellent bending loss characteristic. On the other hand, all the components of the optical fiber 60 are composed of transparent members, and therefore, when a deposit is attached to the surface of the exposed portion 61, the deposit influences internal reflection of light passing through the optical fiber 60.

As shown in FIG. 2, the laser unit 71 and the PD 73 constitute a deposit detector 70 that is disposed outside the chamber 11. The laser unit 71 and the PD 73 are accommodated in a deposit detector box 70a, which is a housing of the deposit detector 70. The laser unit 71 is connected through a glass fiber 72 to one end of the optical fiber 60, using a connector 55a. The PD 73 is connected through a glass fiber 74 to another end of the optical fiber 60, using a connector 55b.

The deposit detector 70 is connected to a personal computer (PC) 90 that functions as a controller of the substrate processing apparatus 10 shown in FIG. 1. The PC 90 controls the emission of incident light from the laser unit 71, acquires data indicating a result of light reception by the PD 73, and performs feedback control of automatically controlling the substrate processing apparatus 10 based on the acquired data. With the feedback control, cleaning of the interior of the chamber 11 is performed, and conditions for etching processing on the wafer W are changed, whereby the reliability of automatic control by the substrate processing apparatus 10 can be improved.

The operation of the deposit monitor apparatus 50 shown in FIG. 2 will be described below.

The laser unit 71 emits toward the optical fiber 60 incident light having a single wavelength different from the wavelength of light which is emitted from plasma generated in the etching processing. It should be noted that the wavelength of incident light is not limited to a single wavelength. The PD 73 functions as an optical sensor for receiving light having passed through the optical fiber 60 and detecting the amount of light received. The amount of light detected (monitored) by the PD 73 is input to the PC 90 as data. The PC 90 then analyzes the inputted data to calculate a change in the amount of incident light from the laser unit 71, i.e., a change in the transmittance (increase rate or damping rate) of the incident light.

During the etching processing on the wafer W in the chamber 11, reaction products, particles, and the like generated in the chamber 11 are deposited as a deposit on the surface of the exposed portion 61 of the optical fiber 60. Part of the incident light from the laser unit 71 is dispersed and arrives at the surface of the optical fiber 60, while passing through the optical fiber 60. That part of the incident light is reflected by the deposit on the surface of the exposed portion 61. The reflected incident light having passed through the optical fiber 60 enters the PD 73 together with direct incident light from the laser unit 71. Based on the amount of light detected by the PD 73, the PC 90 calculates a change in the amount of incident light from the laser unit 71. In this case, the PC 90 detects the increase rate of the amount of light. The reflectivity of dispersed incident light by the deposit varies depending on the thickness of the deposit. Thus, the increase rate of the amount of light detected by the PC 90 is closely related to the thickness of the deposit attached to the surface of the exposed portion 61. Namely, based on the increase rate of the amount of light detected by the PC 90, the thickness of the deposit on the surface of the exposed portion 61 can be calculated.

In this embodiment, the thickness of deposit attached to the surface of the exposed portion 61 is calculated based on the increase rate of the amount of light detected by the PC 90. When the calculated thickness exceeds a threshold, cleaning of the interior of the chamber 11 is carried out as the feedback control in appropriate timing after completion of the etching processing. It should be noted that when the increase rate of the amount of light is extremely high, the PC 90 may forcefully terminate the etching processing which is being carried out. When the interior of the chamber 11 is cleaned by dry cleaning with plasma, the thickness calculated by the PC 90 gradually decreases. The PC 90 may determine that the dry cleaning which is being carried out reaches an end point when the thickness becomes equal to or less than the threshold, and may terminate the execution of the dry cleaning.

According to the deposit monitoring apparatus 50 shown in FIG. 2, deposit attached to the surface of the exposed portion 61 reflects incident light from the laser unit 71 having been dispersed and arrived at the surface of the optical fiber 60, and the PD 73 detects the sum of the amount of direct incident light from the laser unit 71 and the amount of incident light reflected by the deposit. Therefore, the deposit monitoring apparatus 50 can directly detect the deposit based on the amount of detected light.

The present invention has been described above taking as an example a case where the amount of light detected by the PD 73 increases with increasing deposit thickness, but the present invention may similarly be applied to a case where the amount of light detected by the PD 73 decreases with increasing deposit thickness due to absorption of incident light by a deposit. The PD 73 may be any photodiode as long as it detects at least one of the amount of light and the intensity of light. It should be noted that it is preferable for the PC 90 to calculate the thickness of deposit attached to the surface of the exposed portion 61, considering a possible case where phenomena of the light amount or light intensity decreasing with increasing deposit thickness and of the light amount or light intensity increasing with increasing deposit thickness occur in combination.

Furthermore, it has been described that the deposit thickness is calculated by the PC 90, but the calculation may be performed by the deposit monitoring apparatus 50 instead of the PC 90.

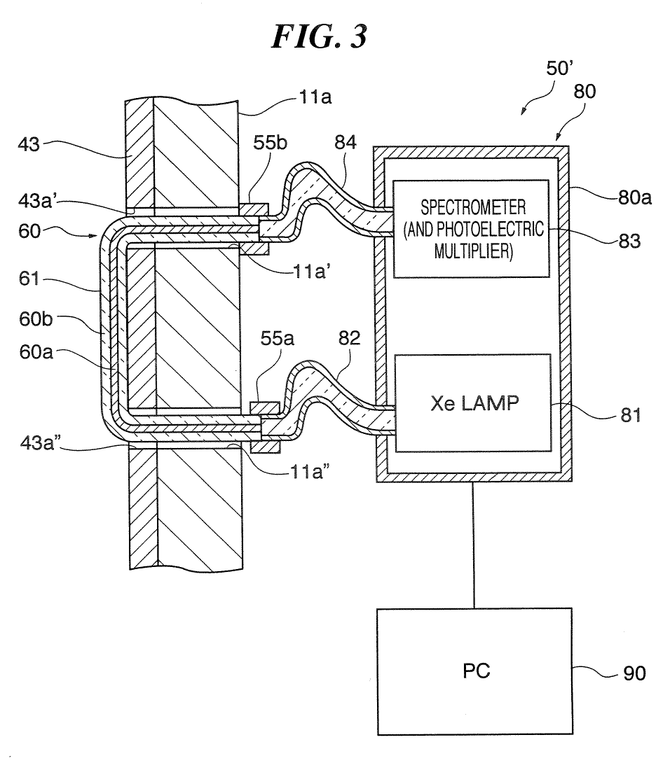

FIG. 3 is a fragmentary sectional view schematically showing the construction of a modification of the deposit monitoring apparatus shown in FIG. 2.

A deposit monitoring apparatus 50′ shown in FIG. 3 is used instead of the deposit monitoring apparatus 50 in FIG. 2. Specifically, the deposit monitoring apparatus 50′ is constructed by detaching from the chamber 11 the deposit detector 70 for the deposit monitoring apparatus 50 attached to the chamber 11 via the glass fibers 72, 74 using the connectors 55a, 55b and then attaching a different deposit detector 80 to the chamber 11 via two glass fibers 82, 84 using the connectors 55a, 55b.

A xenon (Xe) lamp 81 as the light-emitting device and a spectrometer 83 as the light-receiving device are accommodated in a deposit detector box 80a, which is a housing of the deposit detector 80 in FIG. 3. It is preferable that a photoelectric multiplier, a photocounter, a photodiode, or the like be connected to the spectrometer 83.

The Xe lamp 81 emits toward the optical fiber 60 incident light having wavelengths in a wideband spectral range including ultraviolet, visible, and near infrared ranges. The spectrometer 83 receives both direct incident light from the Xe lamp 81 and light reflected by a deposit, separates the received light into a spectrum of wavelengths, and inputs data about the separated light wavelengths to the PC 90. The PC 90 creates a spectral distribution based on the inputted data. When reflecting incident light, the deposit absorbs light whose wavelengths correspond to the components and the composition of the deposit. The absorption of light by the deposit is represented by an absorption spectrum in the spectral distribution. Based on the absorption spectrum in the created spectral distribution, the PC 90 can analyze the components and composition of the deposit on the surface of the exposed portion 61, and based on the result of analysis, the PC 90 can perform the feedback control such as changing the conditions for the etching processing on the wafer W.

It should be noted that a light source other than the Xe lamp 81 may be used in the arrangement shown in FIG. 3. The analysis of the deposit is not limited to the analysis of components, and a variety of analyses can be carried out. A commercial available Fourier transform infrared spectrophotometer (FTIR) may be used as the deposit monitoring apparatus 50′. In this case, the FTIR, rather than the PC 90, creates an infrared absorption spectrum distribution.

The deposit monitoring apparatus 50′ shown in FIG. 3 and the deposit monitoring apparatus 50 shown in FIG. 2 may be at least partially combined.

As described above, according to this embodiment, the optical fiber 60 is used between the light-emitting device and the light-receiving device, a part of the optical fiber 60 (the exposed portion 61) is exposed in the chamber 11, and deposit attached to the exposed portion 61 is directly analyzed. Thus, among apparatus components, only the optical fiber 60 is required to be exposed in the chamber 11 for direct deposit analysis. As a result, the following effects can be achieved.

First, the optical fiber 60 is a thin wire which is compact in size and can be bent. Therefore, the optical fiber 60 is high in the degree of freedom for installation, offering extremely easy replacement at the time of maintenance.

Second, unlike the prior art, it is unnecessary to expose a large-sized member which requires a countermeasure to prevent an abnormal discharge from occurring in the chamber 11. As a result, the degree of freedom for installation of the exposed portion 61 of the optical fiber 60 can be improved, allowing an improvement in the degree of freedom for installation of the deposit monitoring apparatus 50 or 50′.

Third, commercially available products may be used for the optical fiber 60, the connectors 55a and 55b for the optical fiber 60, and the like, without the need of taking the trouble to prepare a large transparent member such as an internal reflection prism, unlike the prior art. Furthermore, they are available at low costs, thus making it possible to reduce maintenance costs.

It should be noted that, in this embodiment, it preferable for the exposed portion 61 to have a large surface area for improvement of the detection sensitivity of the light-receiving device. Specifically, the length of the exposed portion 61 and/or the thickness of the optical fiber 60 and/or the number of optical fibers 60 is increased. In the case of increasing the number of optical fibers 60, it is preferable that these optical fibers be bundled. To improve the detection sensitivity of the light-receiving device, it is preferable that the temperature of the deposit shield 43 be controlled so as to make at least the temperature of the exposed portion 61 equal to the temperature of the deposit shield 43.

To improve the detection accuracy of the light-receiving device, the following are preferable.

First, the surface of the exposed portion 61 is subjected to mirror-finish processing so as to be microscopically flattened, thereby preventing irregular reflection of light at the surface of the exposed portion. In this case, reflection by a deposit largely contributes to reflection of light at the surface of the exposed portion.

Second, the exposed portion 61 is disposed in a ring form along the inner peripheral surface of the deposit shield 43, thereby detecting the average thickness of a deposit attached to the inner wall of the chamber 11.

Alternatively, for improvement of the detection sensitivity of the light-receiving device, the exposed portion 61 may be fabricated to have a surface rougher than the surface of the deposit shield 43 to thereby microscopically increase the surface area, making it easy for the deposit to attach to the exposed portion 61 more quickly than to the deposit shield 43. This makes it possible to predict the deposition of the deposit on the deposit shield 43 near the exposed portion 61, and therefore, the timing of feedback control by the PC 90 can be determined more precisely.

To prevent an abnormal discharge from occurring in the chamber 11 to thereby generate uniform plasma, the following are preferable.

First, a groove in which the exposed portion 61 is disposed is formed in the inner surface of the deposit shield 43, thereby preventing the exposed portion 61 from protruding from the inner surface of the deposit shield 43.

Second, at least the surface of the exposed portion 61 of the optical fiber 60 on the side of the inner surface of the deposit shield 43 is made flat, and this flattened surface of the exposed portion 61 is abutted against the inner surface of the deposit shield 43, whereby a gap between the inner surface of the deposit shield 43 and the corresponding surface of the exposed portion 61 can be made small.

Third, the length of the exposed portion 61 is shortened, whereby a portion of the optical fiber 60 disposed along the inner surface of the deposit shield 43 can be made small in length, and local detection of the deposit attached to the inner surface of the chamber 11 can be performed. In this case, the deposit shield 43 can easily be attached/detached from the inner wall 11a by attaching/detaching the portion of the optical fiber 60 on the deposit shield 43 side to/from only one of the connectors 55a and 55b.

To maintain the vacuum in the interior of the chamber 11, it is preferable that gaps between the optical fiber 60 and the narrow holes 43a′, 43a″ or 11a′, 11a″ be sealed. For example, O-rings are disposed between the exposed portion 61 and the narrow holes 43a′, 43a″ or 11a′, 11a″.

In the embodiment described above, the exposed portion 61 of the optical fiber 60 is disposed so as to be abutted against the inner surface of the deposit shield 43, but the exposed portion 61 may be placed so as to be exposed to any portion where the deposit is deposited. For example, the exposed portion 61 may be disposed so as to be abutted against a surface of at least one of the inner wall 11a, the ceiling portion 11b, the susceptor 12, and the ceiling electrode plate 38. In the case that the exposed portion 61 is disposed on the ceiling portion 11b or the ceiling electrode plate 38, attachment/detachment (maintenance) of the optical fiber 60 can easily be carried out from above. It should be noted that the exposed portion 61 is not limited to be disposed on a component in the chamber 11. However, with the arrangement in which the exposed portion 61 is disposed on a component in the chamber 11, a deposit during the etching processing on the wafer W can be monitored directly.

The optical fiber 60 used in the embodiment described above is composed of a holey fiber. Alternatively, the optical fiber may be a commercially available optical fiber made of quartz, germanium (Ge)-added quartz, yttria, sapphire, or the like. For example, an optical fiber coated with nontransparent film or having a nontransparent clad may be used. In this case, at least part of the film or the clad is removed so that incident light from the light-emitting device is reflected by a deposit attached to the surface of the optical fiber.

Furthermore, lens adaptors for collecting light may be used as connectors 55a, 55b in the embodiment described above.

Furthermore, as described above, the deposit monitoring apparatuses 50 and 50′ in the embodiment can directly analyze deposit attached to the surface of the exposed portion 61 exposed in the chamber 11. In addition, the deposit monitoring apparatuses 50 and 50′ may function as a condition monitor that acquires information about the state of the surface of the exposed portion 61, which is affected by a processing atmosphere in the chamber 11.

In should be noted that in the embodiment described above the substrate to be processed is a wafer, but may be, for example, a glass substrate for an LCD, an FPD (Flat Panel Display), or the like.

Furthermore, the substrate processing apparatus is not limited to an etching processing apparatus using plasma as described above, but may be a CVD apparatus.

It is to be understood that the present invention may also be achieved by supplying a computer with a storage medium in which is stored a program code of software that realizes the functions of the embodiment described above, and then causing a CPU of the computer to readout and execute the program code stored in the storage medium.

In this case, the program code itself read out from the storage medium realizes the functions of the embodiment described above, and hence the program code and the storage medium in which the program code is stored constitute the present invention.

The storage medium for supplying program code may be any storage medium in which the program code can be stored, for example, a RAM, an NV-RAM, a floppy (registered trademark) disc, a hard disc, a magneto-optical disc, an optical disk such as a CD-ROM, a CD-R, a CD-RW, or a DVD (a DVD-ROM, a DVD-RAM, a DVD-RW or a DVD+RW), a magnetic tape, a nonvolatile memory card, or a ROM. Alternatively, the program code may be supplied to the computer by being downloaded from a database or another computer (not shown) connected to the internet, a commercial network, a local area network or the like.

Moreover, it is to be understood that the functions of the embodiment described above may be accomplished not only by executing a program code read out by a computer, but also by causing an OS (operating system) or the like which operates on the CPU to perform a part or all of the actual operations based on instructions of the program code.

Furthermore, it is to be understood that the functions of the embodiment described above may also be accomplished by writing a program code read out from a storage medium into a memory provided on an expansion board inserted into a computer or in an expansion unit connected to the computer and then causing a CPU or the like provided on the expansion board or in the expansion unit to perform a part or all of the actual operations based on instructions of the program code.

The form of the program code may be an object code, a program code executed by an interpreter, script data supplied to an OS, or the like.

What is claimed is:

1. A substrate processing apparatus comprising:
a deposit monitoring apparatus adapted to monitor deposit in a processing chamber in which predetermined processing is carried out on a substrate to be processed,
wherein said deposit monitoring apparatus comprises an optical fiber disposed so as to be at least partly exposed in the processing chamber, a light-emitting device connected to one end of the optical fiber and adapted to emit incident light to the optical fiber, and a light-receiving device connected to another end of the optical fiber and adapted to receive light having passed through the optical fiber.

2. The substrate processing apparatus according to claim 1, wherein said light-emitting device comprises at least one light source adapted to emit light having a single wavelength, and said light-receiving device comprises an optical sensor adapted to detect at least one of an amount of the received light and an intensity of the received light.

3. The substrate processing apparatus according to claim 2, wherein the single wavelength is different from a wavelength of light emitted in the processing chamber.

4. The substrate processing apparatus according to claim 1, comprising a calculation apparatus adapted to calculate a thickness of deposit attached to a surface of an exposed portion of the optical fiber based on a result of monitoring by said deposit monitoring apparatus.

5. The substrate processing apparatus according to claim 1, wherein said light-emitting device comprises a light source adapted to emit light having wavelengths in a wideband spectral range, and said light-receiving device comprises a spectrometer adapted to separate the received light into a spectrum of wavelengths.

6. The substrate processing apparatus according to claim 5, comprising a spectrum creating apparatus adapted to create a spectral distribution of the light separated into the spectrum of wavelengths.

7. The substrate processing apparatus according to claim 5, wherein said deposit monitoring apparatus analyzes components of the deposit.

8. The substrate processing apparatus according to claim 1, wherein a surface of at least an exposed portion of the optical fiber is mirror-finished.

9. The substrate processing apparatus according to claim 1, wherein said light-emitting device and said light-receiving device are disposed outside the processing chamber.

10. The substrate processing apparatus according to claim 1, wherein a groove in which an exposed portion of the optical fiber is disposed is formed in the processing chamber.

11. The substrate processing apparatus according to claim 1, comprising a controller adapted to perform feedback control based on a result of monitoring by said deposit monitoring apparatus.

12. A deposit monitoring apparatus monitoring deposit in a processing chamber in which predetermined processing is carried out on a substrate to be processed, comprising:
an optical fiber disposed so as to be at least partly exposed in the processing chamber;
a light-emitting device connected to one end of the optical fiber and adapted to emit incident light to the optical fiber; and
a light-receiving device connected to another end of the optical fiber and adapted to receive light having passed through the optical fiber.

13. A deposit monitoring method for monitoring deposit in a processing chamber in which predetermined processing is carried out on a substrate to be processed, comprising:
a light emitting step of emitting incident light to one end of an optical fiber disposed so as to be at least partly exposed in the processing chamber; and
a light receiving step of receiving light having passed through the optical fiber from another end of the optical fiber.
